(19) United States
(12) Patent Application Publication
(10) Pub. No.: US 2019/0221643 A1
(43) Pub. Date: Jul. 18, 2019

(54) SEMICONDUCTOR DEVICE FORMED ON A SOI SUBSTRATE

(71) Applicant: DB HITEK CO., LTD., Seoul (KR)

(72) Inventor: Yong Soo Cho, Daejeon (KR)

(21) Appl. No.: 16/248,999

(22) Filed: Jan. 16, 2019

(30) Foreign Application Priority Data
Jan. 16, 2018 (KR) 10-2018-0005355

(51) Int. Cl. H01L 29/10; H01L 27/12; H01L 29/06; H01L 23/66

(52) U.S. Cl. CPC H01L 29/1083; H01L 23/66; H01L 29/0649; H01L 27/1203

(57) ABSTRACT

A semiconductor device formed on a SOI substrate is disclosed. The semiconductor device includes a first active region comprising a source region and a drain region spaced apart from the source region in a channel length direction, a third active region spaced apart from the first active region in a channel width direction, a second active region configured to connect the first active region and the third active region and having a width narrower than the first active region, a gate electrode disposed on the first active region, and an isolation region disposed between the first active region and the third active region.

### CROSS-REFERENCE TO RELATED APPLICATION

This application claims the priority benefit of Korean Patent Application No. 10-2018-0005355, filed on Jan. 16, 2018, and all the benefits accruing therefrom under 35 U.S.C. § 119, the contents of which are incorporated by reference in their entirety.

### TECHNICAL FIELD

The present disclosure relates generally to the field of semiconductor devices with reduced OFF-state capacitance values.

### BACKGROUND

The present disclosure relates to a semiconductor device formed on a Silicon On Insulator (SOI) substrate. More specifically, the present disclosure relates to a semiconductor device including SOI transistors that can be used as a Radio Frequency (RF) switch device.

In general, a semiconductor device such as transistors formed on a SOI substrate may be used as an RF switch device. For example, a plurality of serially coupled SOI transistors may be used as an RF switch capable of handling the power levels in a portable electronic device.

FIG. 1 is a schematic plan view illustrating a conventional semiconductor device used as an RF switch device.

Referring to FIG. 1, a conventional semiconductor device 100 used as an RF switch device includes a well region 110 formed in an upper semiconductor layer of a SOI substrate 102, source and drain regions 120 and 122 formed in the well region 110, a well contact region 130 formed in the well region 110, and a gate electrode 140 formed on the upper semiconductor layer. Further, a gate contact pad 142 and a dummy electrode 144, which are connected with the gate electrode 140, are formed on the upper semiconductor layer, and contact plugs 150 may be formed on the gate contact pad 142, the source and drain regions 120 and 122, and well contact region 130. The well contact region 130 may be formed by an ion implantation process, and the ion implantation process may be performed in a self-aligning manner using the dummy electrode 144.

However, due to a parasitic capacitance between the dummy electrode 144 and the contact plugs 150 and a parasitic capacitance between the dummy electrode 144 and a lower semiconductor layer of the SOI substrate 102, the OFF-state capacitance (C_{off}) of the semiconductor device 100 may be unacceptably high for some purposes, and further, the Figure Of Merit (FOM) of the semiconductor device 100 may be unacceptably low for some purposes.

### SUMMARY

The present disclosure provides a semiconductor device capable of reducing the OFF-state capacitance.

In accordance with an aspect of the present disclosure, a semiconductor device may include a first active region comprising a source region and a drain region spaced apart from the source region in a channel length direction, a third active region spaced apart from the first active region in a channel width direction, a second active region configured to connect the first active region and the third active region and having a width narrower than the first active region, a gate electrode disposed on the first active region, and an isolation region disposed between the first active region and the third active region.

In accordance with some exemplary embodiments of the present disclosure, the first active region may further include a first well region having a first conductivity type, and the source region and the drain region may be disposed on the first well region and have a second conductivity type.

In accordance with some exemplary embodiments of the present disclosure, the third active region may include a third well region having the first conductivity type, and the second active region may include a second well region configured to connect the first well region and the third well region and having the first conductivity type.

In accordance with some exemplary embodiments of the present disclosure, the third active region may further include a well contact region disposed on the third well region.

In accordance with some exemplary embodiments of the present disclosure, the semiconductor device may further include a substrate comprising a lower semiconductor layer, an upper semiconductor layer and a buried oxide layer disposed between the lower and upper semiconductor layers, wherein the first, second and third active regions may be disposed in the upper semiconductor layer.

In accordance with some exemplary embodiments of the present disclosure, the source region and the drain region may have the same thickness as the upper semiconductor layer.

In accordance with some exemplary embodiments of the present disclosure, the source region and the drain region may have a second conductivity type, and the first active region may further include a first well region having a first conductivity type and disposed between the source region and the drain region.

In accordance with some exemplary embodiments of the present disclosure, the third active region may include a well contact region having the first conductivity type and the same thickness as the upper semiconductor layer, and the second active region may include a second well region configured to connect the first well region and the well contact region and having the first conductivity type.

In accordance with some exemplary embodiments of the present disclosure, the isolation region may have the same thickness as the upper semiconductor layer and may be disposed on the buried oxide layer.

In accordance with some exemplary embodiments of the present disclosure, the gate electrode may have a width wider than the second active region.

In accordance with some exemplary embodiments of the present disclosure, the semiconductor device may further include a gate contact pad spaced apart from the first active region, wherein the gate electrode may be electrically connected with the gate contact pad.

In accordance with some exemplary embodiments of the present disclosure, the second active region may extend in the channel width direction, and the gate electrode may extend along the second active region.

In accordance with another aspect of the present disclosure, a semiconductor device may include a first active region comprising a plurality of impurity regions each configured to function as a source region or a drain region and arranged in a channel length direction, a third active region spaced apart from the first active region in a channel width direction, a plurality of second active regions configured to connect the first active region and the third active region, a plurality of gate electrodes disposed on the first active region, a first isolation region disposed outside the first active region, the plurality of second active regions and the third active region, and at least one second isolation region disposed inside the first active region, the plurality of second active regions and the third active region.

In accordance with some exemplary embodiments of the present disclosure, the semiconductor device may further include a substrate comprising a lower semiconductor layer, an upper semiconductor layer and a buried oxide layer disposed between the lower and upper semiconductor layers, wherein the first active region, the plurality of second active regions and the third active region may be disposed in the upper semiconductor layer.

In accordance with some exemplary embodiments of the present disclosure, the first active region may further include a first well region comprising at least one channel region disposed between the impurity regions and having a first conductivity type.

In accordance with some exemplary embodiments of the present disclosure, the third active region may include a well contact region having the first conductivity type, and each of the plurality of second active regions may include a second well region configured to electrically connect the first well region and the well contact region and having the first conductivity type.

In accordance with some exemplary embodiments of the present disclosure, the third active region may further include a third well region configured to electrically connect the well contact region and the second well region and having the first conductivity type.

In accordance with some exemplary embodiments of the present disclosure, the first isolation region and the at least one second isolation region may have the same thickness as the upper semiconductor layer and may be disposed on the buried oxide layer.

In accordance with some exemplary embodiments of the present disclosure, the plurality of gate electrodes may have a width wider than that of the plurality of second active regions.

In accordance with some exemplary embodiments of the present disclosure, the semiconductor device may further include a gate contact pad spaced apart from the first active region, wherein each of the plurality of gate electrodes each may include a connecting portion connected to the gate contact pad and an extending portion extending along the plurality of second active regions.

The above summary of the present disclosure is not intended to describe each illustrated embodiment or every implementation of the present disclosure. The detailed description and claims that follow more particularly exemplify these embodiments.

### BRIEF DESCRIPTION OF THE DRAWINGS

Exemplary embodiments can be understood in more detail from the following description taken in conjunction with the accompanying drawings, in which:

FIG. 1 is a schematic plan view illustrating a conventional semiconductor device used as an RF switch device;

FIG. 2 is a schematic plan view illustrating a semiconductor device in accordance with an embodiment of the present disclosure;

FIG. 3 is a cross-sectional view taken along the line III-III as shown in FIG. 2;

FIG. 4 is a cross-sectional view taken along the line IV-IV as shown in FIG. 2;

FIG. 5 is a cross-sectional view taken along the line V-V as shown in FIG. 2;

FIG. 6 is a cross-sectional view illustrating another example of a first active region as shown in FIG. 2;

FIG. 7 is a cross-sectional view illustrating another example of a third active region as shown in FIG. 2;

FIG. 8 is a schematic plan view illustrating a semiconductor device in accordance with another embodiment of the present disclosure;

FIG. 9 is a cross-sectional view taken along the line IX-IX as shown in FIG. 8;

FIG. 10 is a cross-sectional view taken along the line X-X as shown in FIG. 8;

FIG. 11 is a cross-sectional view taken along the line XI-XI as shown in FIG. 8;

FIG. 12 is a cross-sectional view illustrating another example of a first active region as shown in FIG. 8; and

FIG. 13 is a cross-sectional view illustrating another example of a third active region as shown in FIG. 8.

While various embodiments are amenable to various modifications and alternative forms, specifics thereof have been shown by way of example in the drawings and will be described in detail. It should be understood, however, that the intention is not to limit the claimed inventions to the particular embodiments described. On the contrary, the intention is to cover all modifications, equivalents, and alternatives falling within the spirit and scope of the subject matter as defined by the claims.

### DETAILED DESCRIPTION

Hereinafter, embodiments of the present invention are described in more detail with reference to the accompanying drawings. However, the present invention is not limited to the embodiments described below and is implemented in various other forms. Embodiments below are not provided to fully complete the present invention but rather are provided to fully convey the range of the present invention to those skilled in the art.

In the specification, when one component is referred to as being on or connected to another component or layer, it can be directly on or connected to the other component or layer, or an intervening component or layer may also be present. Unlike this, it will be understood that when one component is referred to as directly being on or directly connected to another component or layer, it means that no intervening component is present. Also, though terms like a first, a second, and a third are used to describe various regions and layers in various embodiments of the present invention, the regions and the layers are not limited to these terms.

Terminologies used below are used to merely describe specific embodiments, but do not limit the present invention. Additionally, unless otherwise defined here, all the terms including technical or scientific terms, may have the same meaning that is generally understood by those skilled in the art.

Embodiments of the present invention are described with reference to schematic drawings of ideal embodiments. Accordingly, changes in manufacturing methods and/or allowable errors may be expected from the forms of the drawings. Accordingly, embodiments of the present invention are not described being limited to the specific forms or areas in the drawings, and include the deviations of the forms. The areas may be entirely schematic, and their forms may not describe or depict accurate forms or structures in any given area, and are not intended to limit the scope of the present invention.

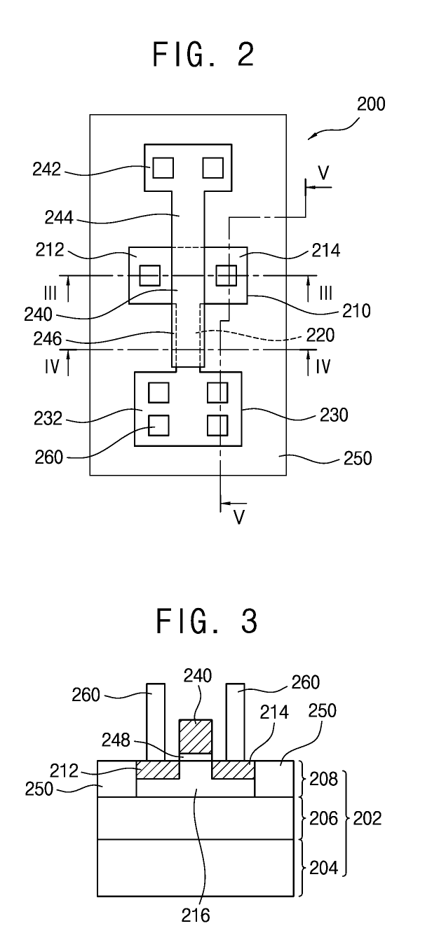

FIG. 2 is a schematic plan view illustrating a semiconductor device in accordance with an exemplary embodiment of the present disclosure.

Referring FIG. 2, a semiconductor device 200, in accordance with an embodiment of the present disclosure, may include a first active region 210, a third active region 230 spaced apart from the first active region 210, a second active region 220 connecting the first active region 210 and the third active region 230 with each other and having a width narrower than the first active region 210, a gate electrode 240 disposed on the first active region 210, and an isolation region 250 disposed at least partially between the first active region 210 and the third active region 230. Particularly, the first active region 210 may include a source region 212 and a drain region 214 spaced apart from the source region 212 in a channel length direction, and the third active region 230 may be spaced apart from the first active region 210 in a channel width direction. Further, the third active region 230 may include a well contact region 232.

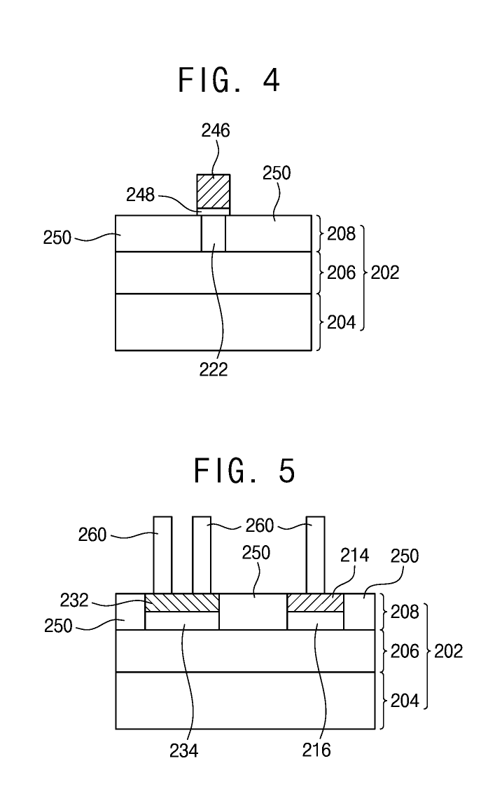

FIG. 3 is a cross-sectional view taken along the line III-III as shown in FIG. 2, FIG. 4 is a cross-sectional view taken along the line IV-IV as shown in FIG. 2, and FIG. 5 is a cross-sectional view taken along the line V-V as shown in FIG. 2.

Referring to FIGS. 2 to 5, the semiconductor device 200 may be formed on a SOI substrate 202. The SOI substrate 202 may include a lower semiconductor layer 204, an upper semiconductor layer 208, and a buried oxide layer 206 disposed between the lower and upper semiconductor layers 204 and 208, and the first, second and third active regions 210, 220 and 230 may be formed in the upper semiconductor layer 208. Further, the isolation region 250 may have the same thickness as the upper semiconductor layer 208 and may be disposed on the buried oxide layer 206. It should be understood throughout the application that the terms “same thickness” are approximate and do not mean that the thicknesses cannot vary from one another by expected tolerances.

The isolation region 250 may be formed by a shallow trench isolation (STI) process and may be made of silicon oxide or silicon nitride. For example, the upper semiconductor layer 208 may be partially removed to form a trench (not shown) defining the first, second and third active regions 210, 220 and 230, and the isolation region 250 may be formed by filling the trench with silicon oxide or silicon nitride. Particularly, the buried oxide layer 206 may be partially exposed by the trench, and portions of the upper semiconductor layer 208 defined by the isolation region 250 may be used as the first, second and third active regions 210, 220 and 230, respectively.

The first active region 210 may include a first well region 216 as shown in FIG. 3, and the source and drain regions 212 and 214 may be disposed on the first well region 216. The first well region 216 may have a first conductivity type, and the source and drain regions 212 and 214 may have a second conductivity type. For example, the first well region 216 may be a p-type impurity region, and the source and drains regions 212 and 214 may be n-type impurity regions. Though not shown in figures, the first well region 216 may include a channel region disposed between the source region 212 and the drain region 214, and the gate electrode 240 may be disposed on the channel region. Further, a gate insulating layer 248 may be disposed between the gate electrode 240 and the channel region.

The third active region 230 may include a third well region 234 having the first conductivity type, as shown in FIG. 5. The well contact region 232 may be disposed on the third well region 234 and may have the first conductivity type. Further, the well contact region 232 may have an impurity concentration higher than that of the third well region 234.

The second active region 220 may include a second well region 222 having the first conductivity type and connecting the first well region 216 and the third well region 234 as shown in FIG. 4. For example, the first, second and third well regions 216, 222 and 234 may be simultaneously formed by an ion implantation process after forming the isolation region 250.

Referring again to FIG. 2, the second active region 220 may have a width narrower than those of the first and third active regions 210 and 230, and the gate electrode 240 may have a width wider than the width of the second active region 220.

The semiconductor device 200 may include a gate contact pad 242 spaced apart from the first active region 210, and the gate electrode 240 may be electrically connected with the gate contact pad 242. For example, the gate electrode 240 may include a connecting portion 244 connected to the gate contact pad 242.

Further, the second active region 220 may longitudinally extend in the channel width direction, and the gate electrode 240 may include an extending portion 246 extending along the second active region 220. The extending portion 246 of the gate electrode 240 may be disposed on the second active region 220 and may have a width wider than the width of the second active region 220.

For example, an insulating layer and a conductive layer may be sequentially formed on the SOI substrate 202, and the gate electrode 240, the gate contact pad 242 and the gate insulating layer 248 may then be formed by patterning the conductive layer and the insulating layer. The gate insulating layer 248 may be made of silicon oxide, and the gate electrode 240 and the gate contact pad 242 may be made of impurity doped polysilicon, for example.

The source region 212 and the drain region 214 may be formed by an ion implantation process using n-type impurities after forming the gate electrode 240. Particularly, the ion implantation process for forming the source and drain regions 212 and 214 may be performed in a self-aligning manner using the gate electrode 240.

The well contact region 232 may be formed by an ion implantation process using p-type impurities after formation of the extending portion 246 as described above. Particularly, the ion implantation process for forming the well contact region 232 may be performed in a self-aligning manner using the extending portion 246 of the gate electrode 240. Because the width of the extending portion 246 is wider than the width of the second active region 220, the p-type impurities may be prevented from being implanted into the second active region 220.

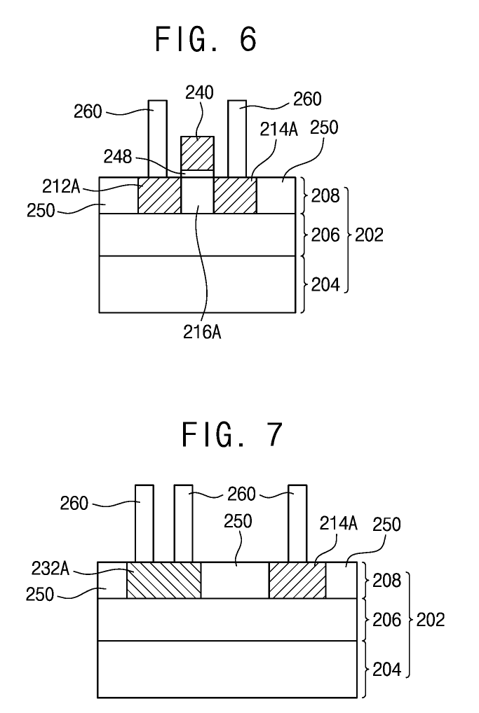

FIG. 6 is a cross-sectional view illustrating another example of the first active region 210 as shown in FIG. 2, taken along the channel length direction.

Referring to FIG. 6, the first active region 210 may include a source region 212A, a drain region 214A, and a first well region 216A disposed between the source and drain regions 212A and 214A. The first well region 216A may have the first conductivity type, and the source and drain regions 212A and 214A may have the second conductivity type. Particularly, the source region 212A, the drain region 214A and the first well region 216A may have the same thickness as the upper semiconductor layer 208. That is, the source region 212A, the first well region 216A and the drain region 214A may be sequentially disposed in the channel length direction. At this time, an upper portion of the first well region 216A may be used as a channel region of the semiconductor device 200.

FIG. 7 is a cross-sectional view illustrating another example of the third active region 230 and first active region 210 as shown in FIG. 2, taken along the channel width direction and according to an embodiment.

Referring to FIG. 7, the third active region 230 may include a well contact region 232A having the first conductivity type. Particularly, the well contact region 232A may have the same thickness as the upper semiconductor layer 208, and the second well region 222 may connect the first well region 216A and the well contact region 232A with each other.

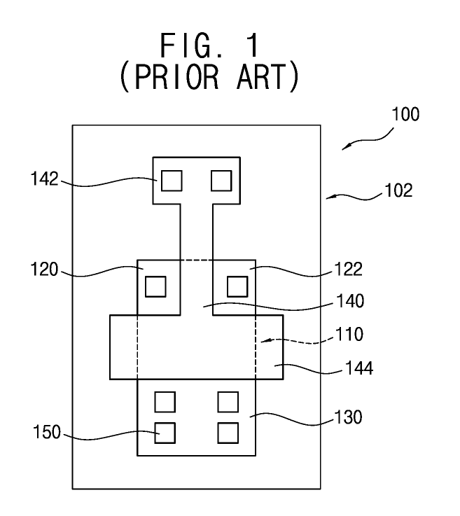

Referring again to FIG. 2, contact plugs 260 may be disposed on the source region 212, the drain region 214, the well contact region 232 and the gate contact region 242. In accordance with the exemplary embodiment of the present disclosure as described above, the dummy electrode 144 for forming the well contact region 130 (refer to FIG. 1) is not used as compared with the prior art. As a result, the parasitic capacitance caused by the dummy electrode 144 may be removed, and the OFF-state capacitance of the semiconductor device 200 may thus be reduced compared to such devices. Further, the FOM of the semiconductor device 200 may be significantly improved.

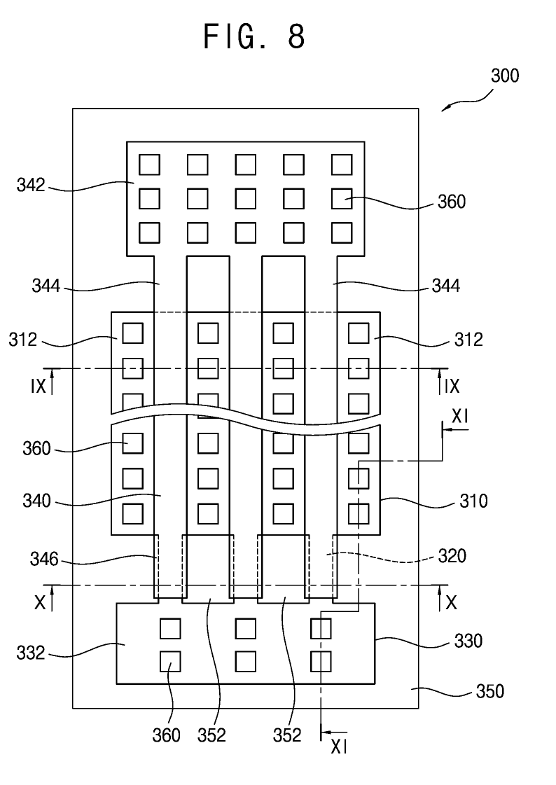

FIG. 8 is a schematic plan view illustrating a semiconductor device in accordance with another exemplary embodiment of the present disclosure.

Referring FIG. 8, a semiconductor device 300 may include a first active region 310 including impurity regions 312 each functioning as a source region or a drain region and arranged along a channel length direction, a third active region 330 spaced apart from the first active region 310 in a channel width direction, second active regions 320 connecting the first active region 310 and the third active region 330, gate electrodes 340 disposed on the first active region 310, a first isolation region 350 disposed outside the first active region 310, the second active regions 320 and the third active region 330, and second isolation regions 352 each disposed inside a region that is circumscribed by the first active region 310, one or more of the second active regions 320, and the third active region 330.

For example, the impurity regions 312 may extend parallel to each other in the channel width direction, and the gate electrodes 340 may extend parallel to each other between the impurity regions 312.

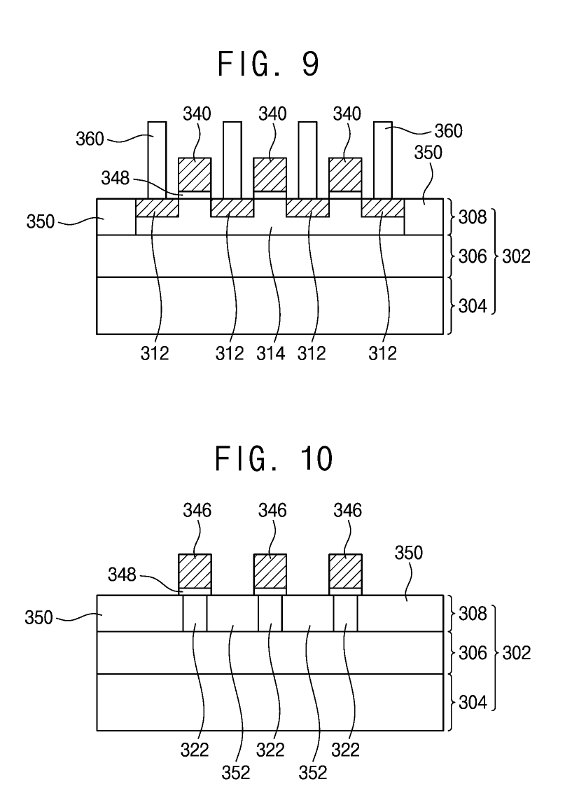

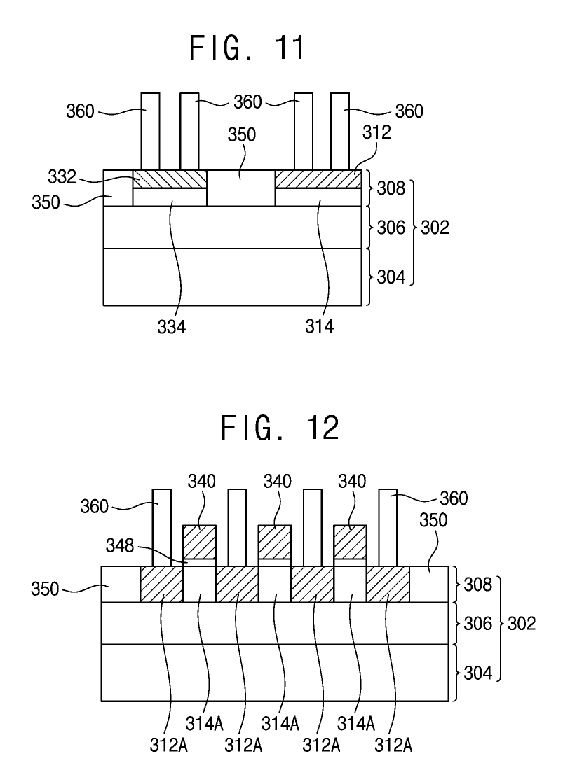

FIG. 9 is a cross-sectional view taken along the line IX-IX as shown in FIG. 8, FIG. 10 is a cross-sectional view taken along the line X-X as shown in FIG. 8, and FIG. 11 is a cross-sectional view taken along the line XI-XI as shown in FIG. 8.

Referring to FIGS. 8 to 11, the semiconductor device 300 may be formed on a SOI substrate 302. The SOI substrate 302 may include a lower semiconductor layer 304, an upper semiconductor layer 308, and a buried oxide layer 306 disposed between the lower and upper semiconductor layers 304 and 308, and the first, second and third active regions 310, 320 and 330 may be formed in the upper semiconductor layer 308. Further, the first and second isolation regions 350 and 352 may have the same thickness as the upper semiconductor layer 308 and may be disposed on the buried oxide layer 306.

The first and second isolation regions 350 and 352 may be formed by a shallow trench isolation (STI) process and may be made of silicon oxide or silicon nitride. For example, the upper semiconductor layer 308 may be partially removed to form a first trench (not shown) and second trenches (not shown) defining the first, second and third active regions 310, 320 and 330, respectively, and the first isolation region 350 and the second isolation regions 352 may be formed by filling the first and second trenches with silicon oxide or silicon nitride. Particularly, the buried oxide layer 306 may be partially exposed by the first and second trenches in other embodiments, and portions of the upper semiconductor layer 308 defined by the first and second isolation regions 350 and 352 may be used as the first, second and third active regions 310, 320 and 330, respectively.

The first active region 310 may include a first well region 314 as shown in FIG. 9, and the impurity regions 312 may be disposed on the first well region 314. The first well region 314 may have a first conductivity type, and the impurity regions 312 may have a second conductivity type. For example, the first well region 314 may be a p-type impurity region, and the impurity regions 312 may be n-type impurity regions. Though not shown in the figures, the first well region314 may include channel regions disposed between any of the impurity regions 312, and the gate electrodes 340 may be each disposed on the channel regions. Further, gate insulating layers 348 may be disposed between the gate electrodes 340 and the channel regions.

The third active region 330 may include a third well region 334 having the first conductivity type as shown in FIG. 11. A well contact region 332 having the first conductivity type may be disposed on the third well region 334. Further, the well contact region 332 may have an impurity concentration higher than that of the third well region 334.

The second active regions 320 may also include a second well region 322 having the first conductivity type as shown in FIG. 10. Further, the second active regions 320 may connect the first well region 314 and the third well region 334. For example, the first, second and third well regions 314, 322 and 334 may be simultaneously formed by an ion implantation process using p-type impurities after forming the first and second isolation regions 350 and 352. Particularly, the first isolation region 350 may be disposed outside the second well regions 322, and the second isolation regions 352 may be disposed between the second well regions 322.

Referring again to FIG. 8, the semiconductor device 300 may include a gate contact pad 342 spaced apart from the first active region 310, and the gate electrodes 340 may be electrically connected with the gate contact pad 342. For example, the gate electrodes 340 may include a connecting portion 344 electrically connected to the gate contact pad 342.

Further, the second active regions 320 may extend along the channel width direction, and the gate electrodes 340 may include an extending portion 346 extending along the second active regions 320, respectively. The extending portions 346 of the gate electrodes 340 may be disposed on the second active regions 320, and may have a width wider than the width of the second active regions 320.

For example, an insulating layer and a conductive layer may be sequentially formed on the SOI substrate 302, and the gate electrodes 340, the gate contact pad 342 and the gate insulating layers 348 may then be formed by patterning the conductive layer and the insulating layer. The gate insulating layers 348 may be made of silicon oxide, and the gate electrodes 340 and the gate contact pad 342 may be made of impurity doped polysilicon, in one embodiment.

The impurity regions 312 may be formed by an ion implantation process using n-type impurities after forming the gate electrodes 340. Particularly, the ion implantation process for forming the impurity regions 312 may be performed in a self-aligning manner using the gate electrodes 340.

The well contact region 332 may be formed by an ion implantation process using p-type impurities. Particularly, the ion implantation process for forming the well contact region 332 may be performed in a self-aligning manner using the extending portions 346 of the gate electrodes 340. Because the width of the extending portions 346 is wider than the width of the second active regions 320, the p-type impurities may be prevented from being implanted into the second active regions 320.

FIG. 12 is a cross-sectional view illustrating another example of the first active region 310 as shown in FIG. 8.

Referring to FIG. 12, the first active region 310 may include impurity regions 312A functioning as a source region or a drain region, and first well regions 314A disposed between the impurity regions 312A. The first well region 314A may have the first conductivity type, and the impurity regions 312A may have the second conductivity type. Particularly, the impurity regions 312A and the first well regions 314A may have the same thickness as the upper semiconductor layer 308. That is, the impurity regions 312A and the first well regions 314A may be alternately arranged in the channel length direction, and may extend in parallel to each other in the channel width direction. At this time, upper portions of the first well regions 314A may be used as channel regions of the semiconductor device 300.

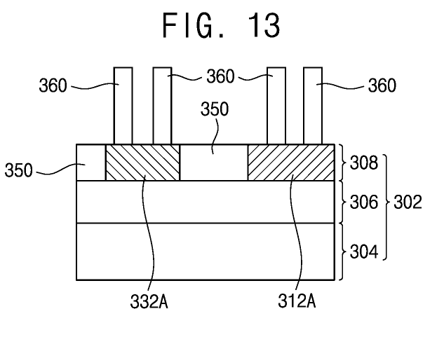

FIG. 13 is a cross-sectional view illustrating another example of the third active region 330 as shown in FIG. 8.

Referring to FIG. 13, the third active region 330 may include a well contact region 332A having the first conductivity type. Particularly, the well contact region 332A may have the same thickness as the upper semiconductor layer 308, and the second well regions 322 may connect the first well regions 314A and the well contact region 332A with each other.

Referring again to FIG. 8, contact plugs 360 may be disposed on the impurity regions 312, the well contact region 332 and the gate contact region 342. As described above in more detail, this obviates the use of dummy componentry that would otherwise increase the OFF-state capacitance of the device 300.

Although the semiconductor devices 200 and 300 have been described with reference to specific embodiments, they are not limited thereto. Therefore, it will be readily understood by those skilled in the art that various modifications and changes can be made thereto without departing from the spirit and scope of the present disclosure defined by the appended claims.

Various embodiments of systems, devices, and methods have been described herein. These embodiments are given only by way of example and are not intended to limit the scope of the claimed inventions. It should be appreciated, moreover, that the various features of the embodiments that have been described may be combined in various ways to produce numerous additional embodiments. Moreover, while various materials, dimensions, shapes, configurations and locations, etc. have been described for use with disclosed embodiments, others besides those disclosed may be utilized without exceeding the scope of the claimed inventions.

Persons of ordinary skill in the relevant arts will recognize that the subject matter hereof may comprise fewer features than illustrated in any individual embodiment described above. The embodiments described herein are not meant to be an exhaustive presentation of the ways in which the various features of the subject matter hereof may be combined. Accordingly, the embodiments are not mutually exclusive combinations of features; rather, the various embodiments can comprise a combination of different individual features selected from different individual embodiments, as understood by persons of ordinary skill in the art. Moreover, elements described with respect to one embodiment can be implemented in other embodiments even when not described in such embodiments unless otherwise noted.

Although a dependent claim may refer in the claims to a specific combination with one or more other claims, other embodiments can also include a combination of the dependent claim with the subject matter of each other dependent claim or a combination of one or more features with other dependent or independent claims. Such combinations are proposed herein unless it is stated that a specific combination is not intended.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

For purposes of interpreting the claims, it is expressly intended that the provisions of 35 U.S.C. § 112(f) are not to be invoked unless the specific terms “means for” or “step for” are recited in a claim.

1. A semiconductor device comprising:
a first active region comprising a source region and a drain region spaced apart from the source region in a channel length direction, the first active region defining a width in the channel length direction;
a third active region spaced apart from the first active region in a channel width direction;
a second active region disposed between and electrically connecting the first active region and the third active region, the second active region defining a width narrower than the width of the first active region;
a gate electrode disposed on the first active region; and
an isolation region disposed between the first active region and the third active region.

2. The semiconductor device of claim 1, wherein the first active region further comprises a first well region having a first conductivity type, and
the source region and the drain region are disposed on the first well region and both have a second conductivity type that is different from the first conductivity type.

3. The semiconductor device of claim 2, wherein the third active region comprises a third well region having the first conductivity type, and
the second active region comprises a second well region configured to connect the first well region and the third well region, the second active region having the first conductivity type.

4. The semiconductor device of claim 3, wherein the third active region further comprises a well contact region disposed on the third well region.

5. The semiconductor device of claim 1, further comprising a substrate defining a lower semiconductor layer, an upper semiconductor layer and a buried oxide layer disposed between the lower and upper semiconductor layers,
wherein the first, second and third active regions are all disposed in the upper semiconductor layer.

6. The semiconductor device of claim 5, wherein the source region and the drain region have about the same thickness as the upper semiconductor layer.

7. The semiconductor device of claim 6, wherein the source region and the drain region have a second conductivity type, and
the first active region further comprises a first well region having a first conductivity type and disposed between the source region and the drain region.

8. The semiconductor device of claim 7, wherein the third active region comprises a well contact region having the first conductivity type and about the same thickness as the upper semiconductor layer, and
the second active region comprises a second well region configured to connect the first well region and the well contact region and having the first conductivity type.

9. The semiconductor device of claim 5, wherein the isolation region has about the same thickness as the upper semiconductor layer and is disposed on the buried oxide layer.

10. The semiconductor device of claim 1, wherein the gate electrode has a width wider than the width of the second active region.

11. The semiconductor device of claim 10, further comprising a gate contact pad spaced apart from the first active region,
wherein the gate electrode is electrically connected with the gate contact pad.

12. The semiconductor device of claim 10, wherein the second active region extends in the channel width direction, and the gate electrode extends along the second active region.

13. A semiconductor device comprising:
a first active region comprising a plurality of impurity regions each configured to function as a source region or a drain region, wherein the plurality of impurity regions are arranged in a channel length direction;
a third active region spaced apart from the first active region in a channel width direction;
a plurality of second active regions configured to electrically connect the first active region and the third active region;
a plurality of gate electrodes disposed on the first active region;
a first isolation region arranged to at least partially circumscribe the first active region, the plurality of second active regions and the third active region; and
at least one second isolation region disposed inside the first active region, the plurality of second active regions and the third active region.

14. The semiconductor device of claim 13, further comprising a substrate defining a lower semiconductor layer, an upper semiconductor layer and a buried oxide layer disposed between the lower and upper semiconductor layers,
wherein the first active region, the plurality of second active regions and the third active region are disposed in the upper semiconductor layer.

15. The semiconductor device of claim 14, wherein the first active region further comprises a first well region defining at least one channel region disposed between the plurality of impurity regions and having a first conductivity type.

16. The semiconductor device of claim 15, wherein the third active region comprises a well contact region having the first conductivity type, and
the plurality of second active regions each comprises a second well region configured to electrically connect the first well region and the well contact region and having the first conductivity type.

17. The semiconductor device of claim 16, wherein the third active region further comprises a third well region configured to electrically connect the well contact region and the second well region and having the first conductivity type.

18. The semiconductor device of claim 14, wherein the first isolation region and the at least one second isolation region have about the same thickness as the upper semiconductor layer and are disposed on the buried oxide layer.

19. The semiconductor device of claim 13, wherein the plurality of gate electrodes has a width wider than that of the plurality of second active regions.

20. The semiconductor device of claim 19, further comprising a gate contact pad spaced apart from the first active region,
wherein each of the plurality of gate electrodes comprises a connecting portion connected to the gate contact pad and an extending portion extending along at least one of the plurality of second active regions.
